(19) United States
(12) Patent Application Publication
(10) Pub. No.: US 2025/0006637 A1
(43) Pub. Date: Jan. 2, 2025

(54) THREE-DIMENSIONAL LAMINATED MEMORY DEVICE USING SEMICONDUCTOR ELEMENT

(71) Applicant: Unisantis Electronics Singapore Pte. Ltd., Singapore (SG)

(72) Inventors: Iwao KUNISHIMA, Tokyo (JP); Masakazu KAKUMU, Tokyo (JP); Koji SAKUI, Tokyo (JP); Nozomu HARADA, Tokyo (JP)

(21) Appl. No.: 18/753,598

(22) Filed: Jun. 25, 2024

(30) Foreign Application Priority Data
Jun. 27, 2023 (WO) PCT/JP2023/023821

(51) Int. Cl. H01L 23/528; H10B 12/00

(52) U.S. Cl. CPC H01L 23/5283; H01L 23/528; H10B 12/20

(57) ABSTRACT

A three-dimensional laminated dynamic flash memory device includes a plurality of laminated memory cells on a substrate. In a first memory cell, a semiconductor layer is made of a first semiconductor layer extending in a first direction and a second semiconductor layer connected to one side of the first semiconductor layer and extending in a second direction orthogonal to the first direction in a plan view. The first memory cell includes first and second impurity regions in contact with both ends of the first semiconductor layer in the first direction in the plan view, a third impurity region in contact with an end of the second semiconductor layer opposite to an end thereof in contact with the first semiconductor layer in the plan view, a first gate insulating layer in contact with a side surface of the first semiconductor layer and a first gate conductor layer in contact with the first gate insulating layer in the plan view, and second and third gate conductor layers in contact with respective side surfaces of second and third gate insulating layers in contact with both side surfaces of the second semiconductor layer in the plan view.

### CROSS-REFERENCE TO RELATED APPLICATIONS

This application claims priority to PCT/JP2023/023821, filed Jun. 27, 2023, the entire content of which is incorporated herein by reference.

### BACKGROUND OF THE INVENTION

### 1. Field of the Invention

The present invention relates to a three-dimensional laminated memory device using a semiconductor element.

### 2. Description of the Related Art

In recent years, in development of large scale integration (LSI), high integration, high performance, low power consumption, and high functionality of memory devices using semiconductor elements have been desired.

In addition, high performance of semiconductor memory elements has progressed. For example, there are a dynamic random access memory (DRAM) (for example, see H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) that uses a surrounding gate transistor (SGT) (for example, see Japanese Unexamined Patent Application Publication No. 2-188966; and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) as a selective transistor and that is connected to a capacitor; a phase change RAM (PCRAM) (for example, see H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)) that is connected to a resistance change element; a resistive RAM (ReRAM) (for example, see K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)); a magneto-resistive RAM (MRAM) (for example, see W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) that changes the orientation of a magnetic spin with a current to change the resistance; and a ferroelectric RAM (FeRAM) (for example, see N. Nagel, I. Kunishima: “Key Technologies for High Density FeRAM Applications”, Integrated Ferroelectrics 48(1) pp. 127-137 (2002)) that changes the orientation of ferroelectric polarization with an electric field to store data.

There is also, for example, a 1T-DRAM memory cell (for example, see Japanese Unexamined Patent Application Publication No. 3-171768; M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 35-37 (2010); J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006); E. Yoshida: “A Capacitorless 1T-DRAM Technology Using Gate-Induced Drain-Leakage (GIDL) Current for Low-Power and High-Speed Embedded Memory”, IEEE IEDM (2006); and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4, pp. 765-771 (2007)) that is constituted of one metal oxide semiconductor (MOS) transistor formed on a silicon on insulator (SOI) substrate and not including a capacitor. For example, among positive holes and electrons generated in a channel by an impact ionization phenomenon due to a current between the source and drain of an N-channel MOS transistor, part or all of the positive holes are retained in the channel to write logical memory data “1”. Also, the positive holes are discharged from the channel to write logical memory data “0”. In the memory cell, a “1” written cell and a “0” written cell exist at random for a common selected word line. When an ON voltage is applied to the selected word line, a problem arises in which the potential of the floating cell channel of the selected memory cell connected to the selected word line greatly fluctuates due to the capacitive coupling between the word line gate conductor and the channel. Thus, it is desirable to improve the characteristics that the operation margin is lowered by the potential fluctuation of the floating cell channel and to improve the characteristics that the retention characteristics are lowered because part of the positive holes that are signal charges retained in the channel is discharged.

There is also a twin-transistor MOS transistor memory element in which one memory cell is formed on an SOI substrate using two MOS transistors (for example, see U.S. Patent Application Publication No. 2008/0137394; U.S. Patent Application Publication No. 2003/0111681; and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4, pp. 765-771 (2007)). In the element, an N+ layer, which serves as the source or drain, is formed between floating cell channels of the two MOS transistors in contact with an insulating layer located on the substrate side. The N+ layer electrically isolates the floating cell channels of the two MOS transistors. Positive holes as signal charges are accumulated only in one floating cell channel, and the other MOS transistor serves as a switch for reading the positive holes of the signals accumulated in the other MOS transistor. In this memory cell, since positive holes as signal charges are accumulated in the channel of the one MOS transistor, a problem arises in which the operation margin and data retention characteristics are also lowered as in the memory cell of the above-described 1T-DRAM.

Recently, a new memory cell called a dynamic flash memory (DFM), which is illustrated in part (A) and part (B) of FIG. 6 and is constituted of a MOS transistor on a Si substrate, is proposed (for example, see U.S. Patent Application Publication No. 2023/0077140). In this memory, as illustrated in part (A), a P layer 61 of silicon having a P-type conductivity type containing an acceptor impurity is provided on an Si substrate 80. A semiconductor including an N layer 63a containing a donor impurity is in contact with the P layer 61, a semiconductor including a pillar-shaped N layer 63b standing in a vertical direction and containing a donor impurity is in contact with a portion of the semiconductor including the N layer 63a, and a pillar-shaped P layer 64 having a quadrangular horizontal section and containing an acceptor impurity is further provided thereon. There are a first insulating layer 62 covering a portion of the N layer 63a and a portion of the N layer 63b, and a first gate insulating layer 65 being in contact with the first insulating layer 62 and covering a portion of the P layer 64. Moreover, a first gate conductor layer 82 is in contact with the first insulating layer 62 and the first gate insulating layer 65. A second insulating layer 66 is in contact with the first gate insulating layer 65 and the first gate conductor layer 82. A P layer 68 containing an acceptor impurity is in contact with the P layer 64.

An N+ layer 67a of this memory is connected to a source line SL that is a first wiring conductive layer, an N+ layer 67b is connected to a bit line BL that is a second wiring conductive layer, a gate conductor layer 70 is connected to a word line WL that is a third wiring conductive layer, the first gate conductor layer 82 is connected to a plate line PL that is a fourth wiring conductive layer, and the N layer 63a is connected to a control line CDC that is a fifth wiring conductive layer. The memory is operated by operation on the voltage to be applied to the source line SL, the bit line BL, the plate line PL, the word line WL, and the control line CDC. Part (B) of FIG. 6 is a perspective view of a memory cell structure of an example of related art.

In the above-described dynamic flash memory, the threshold voltage of a metal oxide semiconductor field-effect transistor (MOSFET) formed under the gate conductor layer 70 can be changed by control on the positive hole concentration in the pillar-shaped P layer 64 having the quadrangular horizontal section and containing the acceptor impurity, and the amount of accumulated positive holes can be increased as compared with the 1T-DRAM memory cell, thereby attaining an increase in information retention time, an increase in memory operation margin, a high-speed operation of the memory, and a reduction in power consumption. Further, in both a write operation and an erase operation, for example, the substrate bias does not become unstable in a floating state during the operation of the MOSFET as in the SOI structure, and the semiconductor portion under a gate insulating layer 69 is not completely depleted. Hence there are features that the threshold, the drive current, and the like of the MOSFET are hardly affected by the operation state, and stable writing, erasing, and reading of memory information can be performed.

In the future, dynamic flash memories having such excellent features will be desired to have a significantly large capacity.

The present application relates to a three-dimensional laminated memory device that enables a dynamic flash memory device, which does not include a variable resistance element or a capacitor and can be constituted only of a MOS transistor, to have a large capacity.

### SUMMARY OF THE INVENTION

In the dynamic flash memory device using the semiconductor element that can be constituted only of the MOS transistor, it is necessary to attain a significant reduction in cost and an increase in capacity of the memory cell.

To address the above-described problems, a three-dimensional laminated memory device according to a first aspect of the invention includes a plurality of memory cells in which a semiconductor layer and a first insulating layer are alternately laminated on a substrate in a vertical direction with respect to the substrate. In a first memory cell included in the plurality of memory cells, the semiconductor layer is made of a first semiconductor layer extending in a first direction and a second semiconductor layer connected to one side of the first semiconductor layer and extending in a second direction orthogonal to the first direction in a plan view. The first memory cell includes a first impurity region and a second impurity region in contact with both respective ends of the first semiconductor layer in the first direction in the plan view, a third impurity region in contact with an end portion of the second semiconductor layer opposite to an end portion thereof in contact with the first semiconductor layer in the plan view, a first gate insulating layer in contact with a side surface of the first semiconductor layer opposite to a side surface thereof in contact with the second semiconductor layer and a first gate conductor layer in contact with the first gate insulating layer in the plan view, a second gate insulating layer and a third gate insulating layer in contact with both side surfaces of the second semiconductor layer in the plan view, and a second gate conductor layer in contact with the second gate insulating layer and a third gate conductor layer in contact with the third gate insulating layer.

According to a second aspect of the invention, in the first aspect of the invention, a second memory cell having a same structure as a structure of the first memory cell may be laminated in the vertical direction with respect to the substrate. A gate conductor layer of the second memory cell corresponding to the first gate conductor layer of the first memory cell may be connected to the first gate conductor layer in the vertical direction. A gate conductor layer of the second memory cell corresponding to the second gate conductor layer of the first memory cell may be connected to the second gate conductor layer in the vertical direction. A gate conductor layer of the second memory cell corresponding to the third gate conductor layer of the first memory cell may be connected to the third gate conductor layer in the vertical direction.

According to a third aspect of the invention, in the second aspect of the invention, the first memory cell may include a first wiring conductor layer extending in the second direction in a same plane parallel to the substrate and being in contact with the first impurity region. The first wiring conductor layer may be in contact with an impurity region of a third memory cell corresponding to the first impurity region, the third memory cell being adjacent to the first memory cell in the second direction in the same plane parallel to the substrate and having a same structure as structures of the first and second memory cells.

According to a fourth aspect of the invention, in the second aspect of the invention, the first memory cell may include a third wiring conductor layer extending in the vertical direction with respect to the substrate and being in contact with the third impurity region. The third wiring conductor layer may be in contact with an impurity region of the second memory cell corresponding to the third impurity region.

According to a fifth aspect of the invention, in the second aspect of the invention, the first memory cell may include a second wiring conductor layer extending in the vertical direction with respect to the substrate and being in contact with the second impurity region. The second wiring conductor layer may be in contact with an impurity region of the second memory cell corresponding to the second impurity region.

According to a sixth aspect of the invention, in the fifth aspect of the invention, a fourth memory cell having a structure mirror-symmetrical to the structure of the first memory cell with respect to a plane being perpendicular to the substrate and extending in the second direction may be adjacent to the first memory cell in the first direction in a same plane parallel to the substrate. An impurity region of the fourth memory cell corresponding to the second impurity region of the first memory cell may be in contact with the second wiring conductor layer in contact with the second impurity region of the first memory cell.

According to a seventh aspect of the invention, in the fourth aspect of the invention, a fifth memory cell having a structure mirror-symmetrical to the structure of the first memory cell with respect to a plane being perpendicular to the substrate and extending in the first direction may be adjacent to the first memory cell in the second direction in a same plane parallel to the substrate. An impurity region of the fifth memory cell corresponding to the third impurity region of the first memory cell may be in contact with the third wiring conductor layer in contact with the third impurity region of the first memory cell.

According to an eighth aspect of the invention, in the first aspect of the invention, the second semiconductor layer extending in the second direction of the first memory cell may be arranged such that a distance between the second semiconductor layer and the first impurity region is different from a distance between the second semiconductor layer and the second impurity region.

According to a ninth aspect of the invention, in the eighth aspect of the invention, a sixth memory cell may have a structure in which the first memory cell is rotated by 180 degrees with respect to an axis perpendicular to the substrate in a same plane parallel to the substrate. The sixth memory cell may be adjacent to the first memory cell in the second direction in the same plane parallel to the substrate. The second gate conductor layer of the first memory cell may be adjacent to a position facing a gate conductor layer of the sixth memory cell corresponding to the second gate conductor layer of the first memory cell. The first wiring conductor layer in contact with the first impurity region of the first memory cell may be in contact with an impurity region of the sixth memory cell corresponding to the second impurity region of the first memory cell.

According to a tenth aspect of the invention, in the third aspect of the invention, the first memory cell may include a fourth wiring conductor layer extending in the second direction in the same plane parallel to the substrate and being in contact with the second impurity region. The fourth wiring conductor layer may be in contact with an impurity region of the third memory cell corresponding to the second impurity region of the first memory cell, the third memory cell being adjacent to the first memory cell in the second direction in the same plane parallel to the substrate.

According to an eleventh aspect of the invention, in the seventh aspect of the invention, the first memory cell may include a fifth wiring conductor layer extending in the second direction in the same plane parallel to the substrate and being in contact with the second impurity region. The fifth wiring conductor layer may be in contact with an impurity region of a fifth memory cell corresponding to the second impurity region of the first memory cell, the fifth memory cell being adjacent to the first memory cell in the second direction in the same plane parallel to the substrate.

According to a twelfth aspect of the invention, in the ninth aspect of the invention, the first memory cell may include a sixth wiring conductor layer extending in the second direction in the same plane parallel to the substrate and being in contact with the second impurity region. The sixth wiring conductor layer may be in contact with an impurity region of the sixth memory cell corresponding to the second impurity region of the first memory cell, the sixth memory cell being adjacent to the first memory cell in the second direction in the same plane parallel to the substrate.

### BRIEF DESCRIPTION OF THE DRAWINGS

FIG. 1A is a schematic partial perspective view illustrating the structure of a three-dimensional laminated memory device according to a first embodiment of the disclosure, in which an insulating layer is not illustrated.

FIG. 1B is a schematic partial plan view illustrating the structure of the three-dimensional laminated memory device according to the first embodiment of the disclosure, in which the insulating layer is not illustrated.

FIG. 1C is a schematic partial sectional view in a vertical direction with respect to a substrate taken along line x1-x2 indicated in FIG. 1B, illustrating the structure of the three-dimensional laminated memory device according to the first embodiment of the disclosure.

FIG. 1D is a schematic partial sectional view in the vertical direction with respect to the substrate taken along line x3-x4 indicated in FIG. 1B, illustrating the structure of the three-dimensional laminated memory device according to the first embodiment of the disclosure.

FIG. 1E is a schematic partial sectional view in the vertical direction with respect to the substrate taken along line y1-y2 indicated in FIG. 1B, illustrating the structure of the three-dimensional laminated memory device according to the first embodiment of the disclosure.

FIG. 2A is a schematic partial perspective view illustrating a second structure of a three-dimensional laminated memory device according to a second embodiment of the disclosure, in which an insulating layer is not illustrated.

FIG. 2B-1 is a schematic partial perspective view illustrating a third structure of a three-dimensional laminated memory device according to a third embodiment of the disclosure, in which an insulating layer is not illustrated.

FIG. 2B-2 is a schematic partial plan view illustrating the structure of the three-dimensional laminated memory device according to the third embodiment of the disclosure, in which the insulating layer is not illustrated.

FIG. 2B-3 is a schematic partial sectional view in a vertical direction with respect to a substrate taken along line x5-x6 indicated in FIG. 2B-2, illustrating the structure of the three-dimensional laminated memory device according to the third embodiment of the disclosure.

FIG. 2B-4 is a schematic partial sectional view in the vertical direction with respect to the substrate taken along line x7-x8 indicated in FIG. 2B-2, illustrating the structure of the three-dimensional laminated memory device according to the third embodiment of the disclosure.

FIG. 2B-5 is a schematic partial sectional view in the vertical direction with respect to the substrate taken along line x9-x10 indicated in FIG. 2B-2, illustrating the structure of the three-dimensional laminated memory device according to the third embodiment of the disclosure.

FIG. 2C is a schematic partial perspective view illustrating a fourth structure of a three-dimensional laminated memory device according to a fourth embodiment of the disclosure, in which an insulating layer is not illustrated.

FIG. 2D is a schematic partial perspective view illustrating a fifth structure of a three-dimensional laminated memory device according to a fifth embodiment of the disclosure, in which an insulating layer is not illustrated.

FIG. 2E is a schematic partial perspective view illustrating a sixth structure of a three-dimensional laminated memory device according to a sixth embodiment of the disclosure, in which an insulating layer is not illustrated.

FIG. 3 is a process flowchart illustrating an embodiment of a method of forming a three-dimensional laminated memory device according to an embodiment described in the specification.

FIG. 4A is a schematic partial perspective view illustrating a method of forming a three-dimensional laminated memory device according to an embodiment of the disclosure.

FIG. 4B is a schematic partial perspective view illustrating the method of forming the three-dimensional laminated memory device according to the embodiment of the disclosure.

FIG. 4C is a schematic partial perspective view illustrating the method of forming the three-dimensional laminated memory device according to the embodiment of the disclosure.

FIG. 4D is a schematic partial perspective view illustrating the method of forming the three-dimensional laminated memory device according to the embodiment of the disclosure.

FIG. 4E is a schematic partial perspective view illustrating the method of forming the three-dimensional laminated memory device according to the embodiment of the disclosure.

FIG. 4F is a schematic partial perspective view illustrating the method of forming the three-dimensional laminated memory device according to the embodiment of the disclosure.

FIG. 4G is a schematic partial perspective view illustrating the method of forming the three-dimensional laminated memory device according to the embodiment of the disclosure.

FIG. 4H is a schematic partial perspective view illustrating the method of forming the three-dimensional laminated memory device according to the embodiment of the disclosure.

FIG. 4I is a schematic partial perspective view illustrating the method of forming the three-dimensional laminated memory device according to the embodiment of the disclosure.

FIG. 4J is a schematic partial perspective view illustrating the method of forming the three-dimensional laminated memory device according to the embodiment of the disclosure.

FIG. 4K is a schematic partial perspective view illustrating the method of forming the three-dimensional laminated memory device according to the embodiment of the disclosure.

FIG. 4L is a schematic partial perspective view illustrating the method of forming the three-dimensional laminated memory device according to the embodiment of the disclosure.

FIG. 4M is a schematic partial perspective view illustrating the method of forming the three-dimensional laminated memory device according to the embodiment of the disclosure.

FIG. 4N is a schematic partial perspective view illustrating the method of forming the three-dimensional laminated memory device according to the embodiment of the disclosure.

FIG. 4O is a schematic partial perspective view illustrating the method of forming the three-dimensional laminated memory device according to the embodiment of the disclosure.

FIG. 4P is a schematic partial perspective view illustrating the method of forming the three-dimensional laminated memory device according to the embodiment of the disclosure.

FIG. 4Q is a schematic partial perspective view illustrating the method of forming the three-dimensional laminated memory device according to the embodiment of the disclosure.

FIG. 4R is a schematic partial perspective view illustrating the method of forming the three-dimensional laminated memory device according to the embodiment of the disclosure.

FIG. 4S is a schematic partial perspective view illustrating the method of forming the three-dimensional laminated memory device according to the embodiment of the disclosure.

FIG. 4T is a schematic partial perspective view illustrating the structure of a three-dimensional laminated memory device according to an embodiment of the disclosure, in which an insulating layer is not illustrated.

FIG. 5A is a schematic partial plan view of a three-dimensional laminated memory device according to an embodiment of the disclosure, illustrating a state during a write operation.

FIG. 5B presents a schematic current-voltage characteristic of the three-dimensional laminated memory device according to the embodiment of the disclosure, illustrating the state during the write operation.

FIG. 5C is a schematic partial plan view of the three-dimensional laminated memory device according to the embodiment of the disclosure, illustrating a state during an erase operation.

FIG. 5D presents a schematic current-voltage characteristic of the three-dimensional laminated memory device according to the embodiment of the disclosure, illustrating the state during the erase operation.

FIG. 6 provides a sectional structural view and a perspective view of a dynamic flash memory of an example of related art.

### DESCRIPTION OF THE PREFERRED EMBODIMENTS

Hereinafter, a three-dimensional laminated memory device using a semiconductor element and a method of manufacturing the three-dimensional laminated memory device according to embodiments of the present invention will be described with reference to the drawings.

### First Embodiment

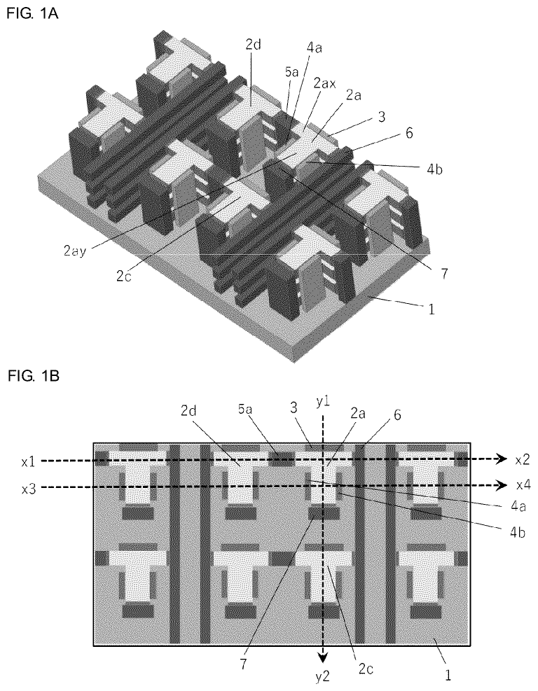

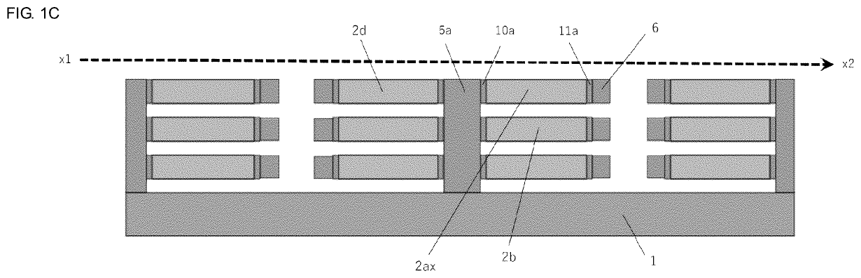

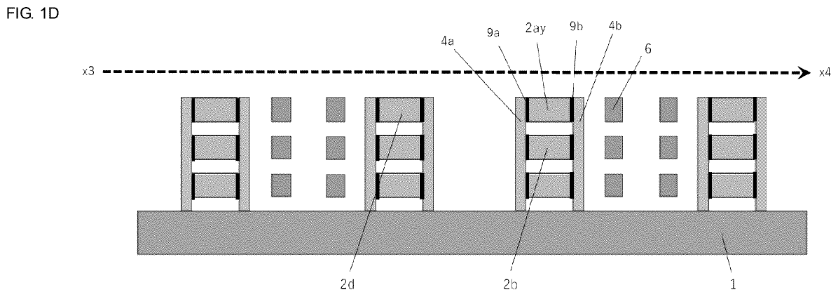

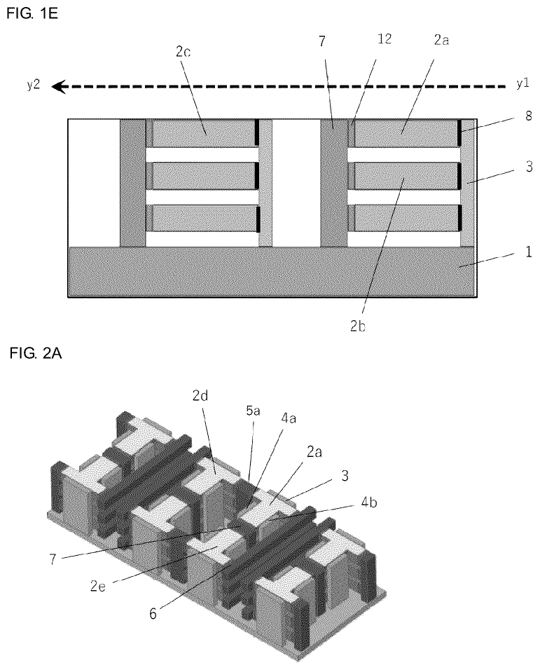

The structure of a memory cell array of a three-dimensional laminated memory cell device according to a first embodiment of the present invention will be described with reference to FIGS. 1A to 1E.

FIG. 1A is a schematic partial perspective view illustrating the memory cell array of the three-dimensional laminated memory cell device according to the first embodiment of the present invention, in which an insulating layer is not illustrated. FIG. 1B is a schematic partial plan view illustrating the structure of FIG. 1A as viewed from above a substrate. FIG. 1C is a schematic partial sectional view in a vertical direction with respect to the substrate taken along line x1-x2 in FIG. 1B. FIG. 1D is a schematic partial sectional view in the vertical direction with respect to the substrate taken along line x3-x4 in FIG. 1B. FIG. 1E is a schematic partial sectional view in the vertical direction with respect to the substrate taken along line y1-y2 in FIG. 1B.

As illustrated in FIG. 1A and FIG. 1B, memory cells 2a constituted of a P-type first semiconductor layer (an example of a “semiconductor layer” in the claims) containing an acceptor impurity are three-dimensionally arrayed in the vertical direction and a horizontal direction with respect to a substrate 1 (an example of a “substrate” in the claims). A memory cell 2a has a substantially T-shaped structure in which a second semiconductor layer 2ay extending in a direction along line y1-y2 indicated in FIG. 1B and having an impurity region at one end is connected to a first semiconductor layer 2ax extending in a direction along line x1-x2 indicated in FIG. 1B and having impurity regions at both ends. A source line 5a (an example of a “second wiring conductor layer” in the claims) is formed in the vertical direction with respect to the substrate and a bit line 6 (an example of a “first wiring conductor layer” in the claims) is formed in the horizontal direction with respect to the substrate at end portions of the first semiconductor layer 2ax.

Additionally, a bottom line 7 (an example of a “third wiring conductor layer” in the claims) is formed in the vertical direction with respect to the substrate at an end portion of the second semiconductor layer 2ay opposite to a surface where the second semiconductor layer 2ay is connected to the first semiconductor layer 2ax.

Additionally, a word line gate electrode 3 (an example of a “first gate conductor layer” in the claims) is formed at a side surface of the first semiconductor layer 2ax opposite to a side surface in contact with the second semiconductor layer 2ay. A plate line gate electrode 4a (an example of a “second gate conductor layer” in the claims) and a plate line gate electrode 4b (an example of a “third gate conductor layer” in the claims) are formed in the vertical direction with respect to the substrate at side surfaces of the second semiconductor layer 2ay.

Further, as illustrated in the sectional views of FIG. 1C and FIG. 1E, a source impurity region 10a (an example of a “second impurity region” in the claims), a drain impurity region 11a (an example of a “first impurity region” in the claims), and a bottom impurity region 12 (an example of a “third impurity region” in the claims), which are constituted of an N+ semiconductor layer containing a donor impurity, are formed between the memory cell 2a, and the source line 5a, the bit line 6, and the bottom line 7.

Further, as illustrated in the sectional views of FIG. 1D and FIG. 1E, a plate line gate insulating layer 9a (an example of a “second gate insulating layer” in the claims), a plate line gate insulating layer 9b (an example of a “third gate insulating layer” in the claims), and a word line gate insulating layer 8 (an example of a “first gate insulating layer” in the claims) are formed between the memory cell 2a, and the plate line gate electrode 4a, the plate line gate electrode 4b, and the word line gate electrode 3.

In the memory cell 2a, the source impurity region 10a, the drain impurity region 11a, and the word line gate electrode 3 constitute a MOS transistor. Further, as illustrated in FIG. 1B, a memory cell 2c (an example of a “third memory cell” in the claims) adjacent to the memory cell 2a in the direction along line y1-y2 on the same plane parallel to the substrate shares the bit line 6 with the memory cell 2a.

Further, as illustrated in FIG. 1B, a memory cell 2d (an example of a “fourth memory cell” in the claims) adjacent to the memory cell 2a in the direction along line x1-x2 on the same plane parallel to the substrate 1 has the structure mirror-symmetrical to that of the memory cell 2a with respect to a plane being perpendicular to the substrate 1 and extending in the direction along line y1-y2. The source line 5a in contact with the memory cell 2a is shared with the memory cell 2d. Further, as illustrated in FIG. 1C to FIG. 1E, a memory cell 2b (an example of a “second memory cell” in the claims) arranged in parallel to the memory cell 2a in the vertical direction with respect to the substrate 1 shares the source line 5a, the bottom line 7, the word line gate electrode 3, and the plate line gate electrodes 4a and 4b with the memory cell 2a.

Note that, as described above, FIG. 1A is the schematic partial perspective view in which the insulating layer in the memory cell array of the three-dimensional laminated memory cell device is not illustrated, and in practice, a space portion of FIG. 1A is filled with the insulating layer.

### Second Embodiment

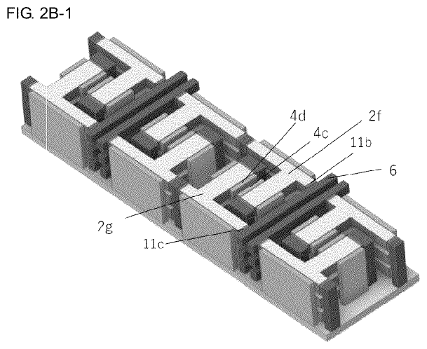

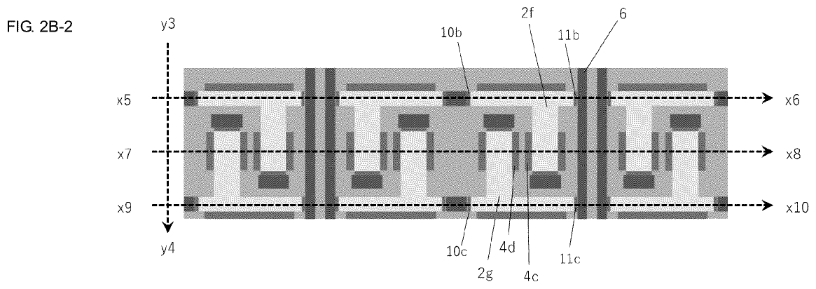

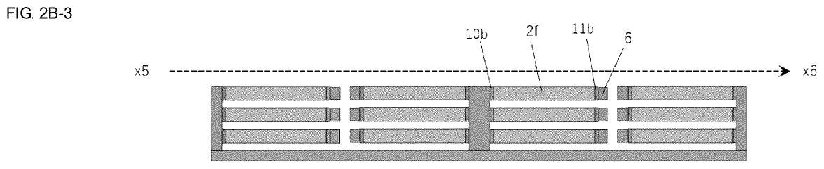

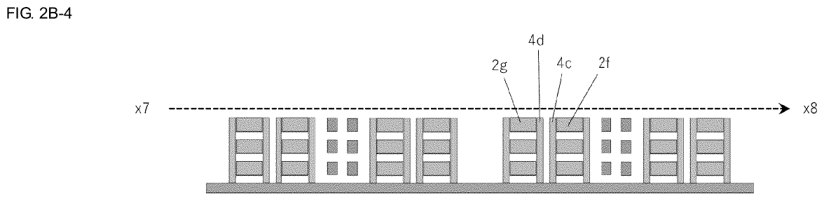

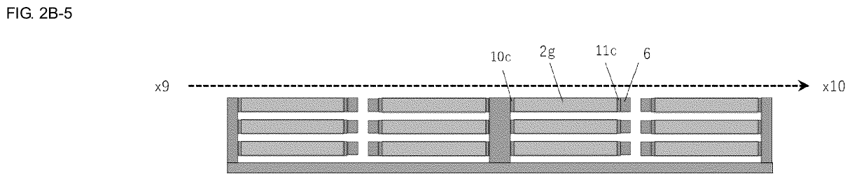

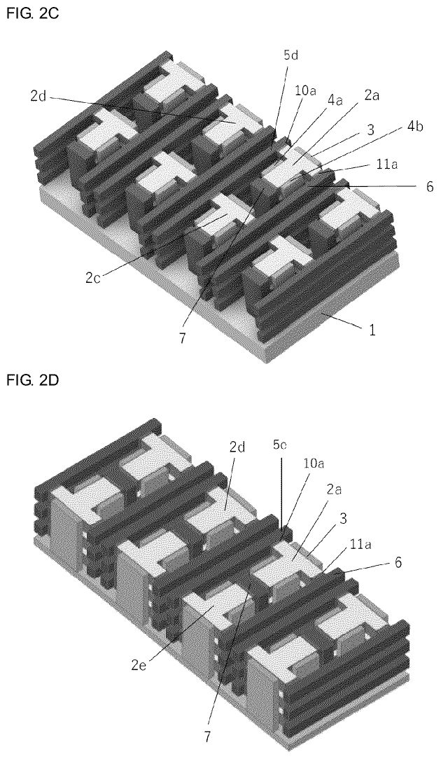

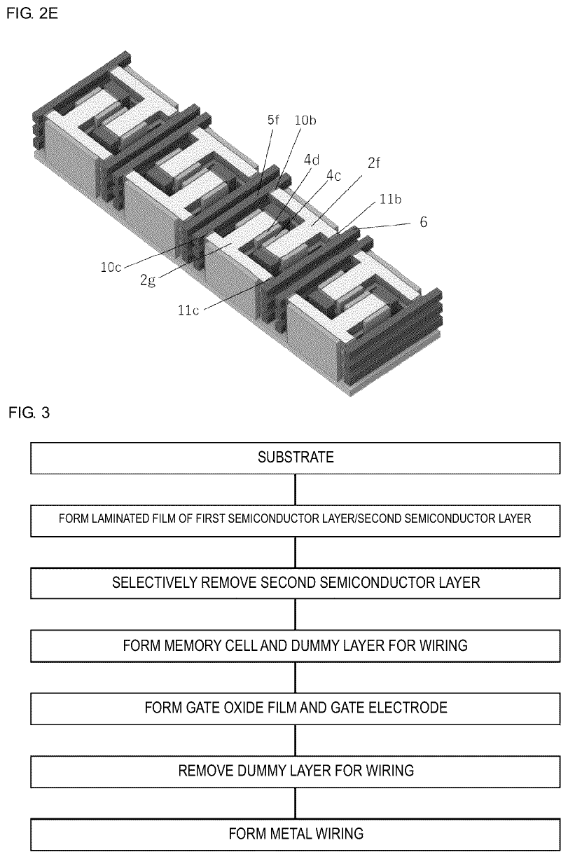

FIG. 2A is a schematic partial perspective view illustrating the structure of a memory cell array of a three-dimensional laminated memory device using a semiconductor element according to a second embodiment of the present invention, in which an insulating layer is not illustrated.

The structure of a single memory cell in FIG. 2A is the same as that of the three-dimensional laminated memory device using the semiconductor element according to the first embodiment of the present invention illustrated in FIG. 1A. The structure of a memory cell array in which memory cells are three-dimensionally arranged in FIG. 2A is different from that in FIG. 1A.

A memory cell 2e (an example of a “fifth memory cell” in the claims) adjacent to the memory cell 2a in the direction along line y1-y2 on the same plane parallel to the substrate 1 has a structure mirror-symmetrical to that of the memory cell 2a with respect to a plane being perpendicular to the substrate 1 and extending in the direction along line x1-x2. The memory cell 2a shares the bottom line 7 with the memory cell 2e.

### Third Embodiment

FIG. 2B-1 is a schematic partial perspective view illustrating the structure of a memory cell array of a three-dimensional laminated memory device using a semiconductor element according to a third embodiment of the present invention, in which an insulating layer is not illustrated.

FIG. 2B-2 is a schematic partial plan view of the structure of FIG. 2B-1 as viewed from above a substrate. FIG. 2B-3 is a schematic partial sectional view in a vertical direction with respect to the substrate taken along line x5-x6 in FIG. 2B-2. FIG. 2B-4 is a schematic partial sectional view in the vertical direction with respect to the substrate taken along line x7-x8 in FIG. 2B-2. FIG. 2B-5 is a schematic partial sectional view in the vertical direction with respect to the substrate taken along line x9-x10 in FIG. 2B-2.

In FIG. 1A, the second semiconductor layer 2ay is connected to the first semiconductor layer 2ax at the center of the first semiconductor layer 2ax in a plan view. In contrast, in the present embodiment, as illustrated in FIG. 2B-2, in a memory cell 2f (an example of a “sixth memory cell” in the claims), a position at which a first semiconductor layer extending in a direction along line x5-x6 indicated in FIG. 2B-2 and a second semiconductor layer extending in a direction along line y3-y4 indicated in FIG. 2B-2 are connected is deviated from a midpoint of the first semiconductor layer between a drain impurity region 11b and a source impurity region 10b existing in the direction along line x5-x6. The structure of a single memory cell is substantially the same except for the difference in the connection position between the first semiconductor layer 2ax and the second semiconductor layer 2ay.

As illustrated in FIG. 2B-2, a memory cell 2g is adjacent to the memory cell 2f in the direction along line y3-y4 indicated in FIG. 2B-2 in the same plane parallel to the substrate 1.

As illustrated in FIG. 2B-2, FIG. 2B-3, and FIG. 2B-5, the shape of the memory cell 2g is similar to the shape of the memory cell 2f rotated by 180 degrees with respect to an axis perpendicular to the substrate 1. A drain impurity region 11c of the memory cell 2g is located at a position corresponding to the source impurity region 10b of the memory cell 2f. A source impurity region 10c of the memory cell 2g is located at a position corresponding to the drain impurity region 11b of the memory cell 2f. A bit line 6 is connected to the drain impurity region 11b and the drain impurity region 11c.

Further, as illustrated in FIG. 2B-4, a plate line 4c of the memory cell 2f is adjacent to a position facing a plate line 4d of the memory cell 2g.

### Fourth Embodiment

FIG. 2C is a schematic partial perspective view illustrating the structure of a memory cell array of a three-dimensional laminated memory device using a semiconductor element according to a fourth embodiment of the present invention, in which an insulating layer is not illustrated.

The structure of a single memory cell in FIG. 2C is the same as that of the three-dimensional laminated memory device using the semiconductor element according to the first embodiment of the present invention illustrated in FIG. 1A. In FIG. 2C, unlike the structure of the memory cell array of the three-dimensional laminated memory device using the semiconductor element according to the first embodiment of the present invention illustrated in FIG. 1A, a source line 5d (an example of a “fourth wiring conductor layer” in the claims) is formed in parallel to a bit line 6 on the same plane parallel to a substrate 1, and is connected to a source impurity region 10a at an end portion of a memory cell 2a.

Further, the source line 5d is shared with a memory cell 2c adjacent to the memory cell 2a on the same plane parallel to the substrate.

### Fifth Embodiment

FIG. 2D is a schematic partial perspective view illustrating the structure of a memory cell array of a three-dimensional laminated memory device using a semiconductor element according to a fifth embodiment of the present invention, in which an insulating layer is not illustrated.

The structure of a single memory cell in FIG. 2D is the same as that of the three-dimensional laminated memory device using the semiconductor element according to the second embodiment of the present invention illustrated in FIG. 2A. Unlike the structure of the memory cell array of the three-dimensional laminated memory device using the semiconductor element according to the second embodiment of the present invention illustrated in FIG. 2A, a source line 5e (an example of a “fifth wiring conductor layer” in the claims) is formed in parallel to a bit line 6 on the same plane parallel to a substrate 1, and is connected to a source impurity region 10a at an end portion of a memory cell 2a.

Further, the source line 5e is shared with a memory cell 2e adjacent to the memory cell 2a on the same plane parallel to the substrate.

### Sixth Embodiment

FIG. 2E is a schematic partial perspective view illustrating the structure of a memory cell array of a three-dimensional laminated memory device using a semiconductor element according to a sixth embodiment of the present invention, in which an insulating layer is not illustrated.

The structure of a single memory cell in FIG. 2E is the same as that of the three-dimensional laminated memory device using the semiconductor element according to the third embodiment of the present invention illustrated in FIG. 2B-1. Unlike the structure of the memory cell array of the three-dimensional laminated memory device using the semiconductor element according to the third embodiment of the present invention illustrated in FIG. 2B-1, a source line 5f (an example of a “sixth wiring conductor layer” in the claims) is formed in parallel to a bit line 6 on the same plane parallel to a substrate 1, and is connected to a source impurity region 10b at an end portion of a memory cell 2f.

Further, the source line 5f is shared with a memory cell 2g adjacent to the memory cell 2f on the same plane parallel to the substrate.

In the structure of the above-described embodiments, the first semiconductor layer constituting the memory cell is the P-type semiconductor layer, and the source impurity region 10a, the drain impurity region 11a, and the bottom impurity region 12 are the N+ semiconductor layer. However, the combination does not imply any limitation, the first semiconductor layer may be an N+ semiconductor layer, and the source impurity region 10a, the drain impurity region 11a, and the bottom impurity region 12 may be a P+ semiconductor layer.

The source line 5a, the bottom line 7, and the bit line 6 are preferably constituted of a metal layer of one of W, Ti, TiN, Cu, Ta, TaN, Co, Mo, and Ru, or a combination thereof. However, the materials do not imply any limitation, and, for example, a semiconductor layer of transition metal silicide, or a semiconductor layer with an impurity doped with high concentration may be used.

In the above-described embodiments, two bit lines 6 adjacent to each other in the same plane parallel to the substrate are electrically insulated from each other via the insulating layer. However, the two adjacent bit lines may have the same potential, or the two adjacent bit lines may be constituted of one bit line.

In the above-described embodiments, the area in which the plate line gate electrode 4a is in contact with the memory cell 2a via the plate line gate insulating layer 9a is preferably larger than the area in which the word line gate electrode 3 is in contact with the memory cell 2a via the word line gate insulating layer 8.

In the above-described embodiments, the space between the memory cell 2a and the memory cell 2b adjacent to each other in the vertical direction with respect to the substrate is filled with the insulating layer; however, the insulating layer may be removed and the plate line gate electrode 4a may be formed so as to surround outer peripheries of the memory cell 2a and the memory cell 2b.

The substrate 1 used in the above-described embodiments may be a semiconductor substrate, or, for example, an amorphous substrate such as a glass substrate.

In the above-described embodiments, only the structure of the memory cell array of the three-dimensional laminated memory device of the present invention has been described in detail. However, a structure in which a portion of a transistor region required for a peripheral circuit for operating the memory cell array is included in a region that is above the substrate surface and has the same depth as that of the memory cell array of the three-dimensional laminated memory device may be employed.

Further, by using a method of the present invention, the portion of the transistor required for the peripheral circuit for operating the memory cell array can be formed simultaneously by using the memory cell 2a, the word line gate insulating layer 8 or the plate line gate insulating layer 9a, the word line gate electrode 3 or the plate line gate electrode 4a, and the source line 5a or the bit line 6 or the bottom line 7, by using substantially the same process as the process of the memory cell array.

Moreover, the transistor required for the peripheral circuit may be a gate-all-around transistor in which a gate electrode surrounds a semiconductor region constituting the transistor, or a double-gate transistor in which two gate electrodes face each other in a direction perpendicular to a substrate.

FIG. 3 is a process flowchart of the first exemplary embodiment for forming a three-dimensional laminated memory cell array according to the present invention. Those skilled in the art will recognize that a method of manufacturing a memory cell array of the three-dimensional laminated memory cell device according to the first embodiment may include any or all of the processes illustrated in FIG. 3. Further, the order of individual processes may be partly altered. The first embodiment may be started with any of the listed processes without departing from the present disclosure.

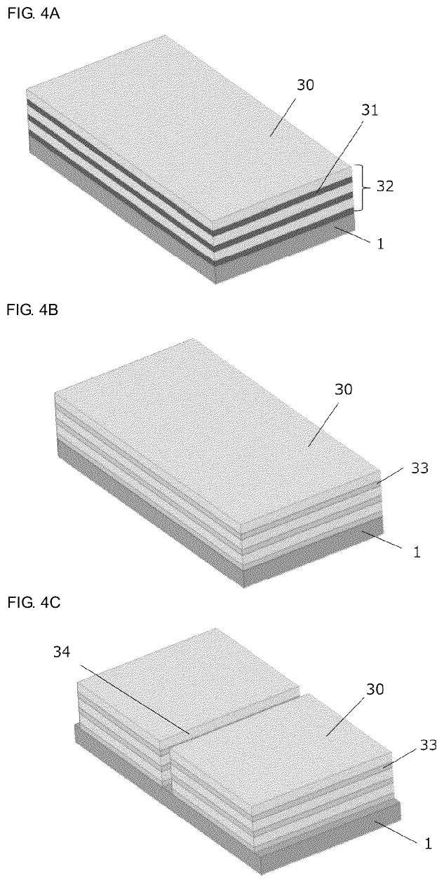

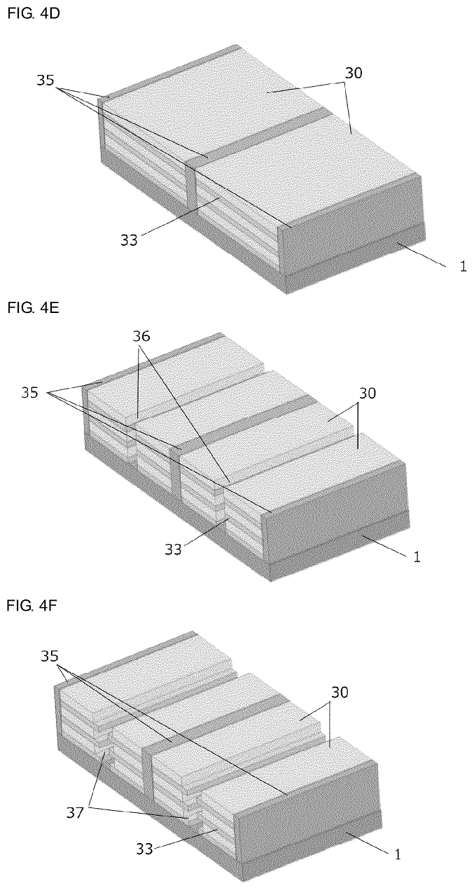

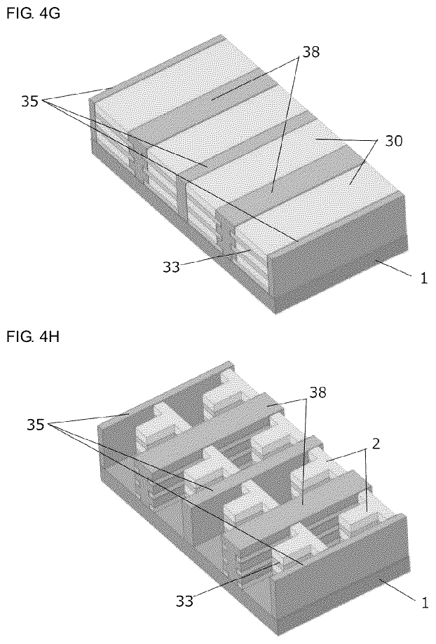

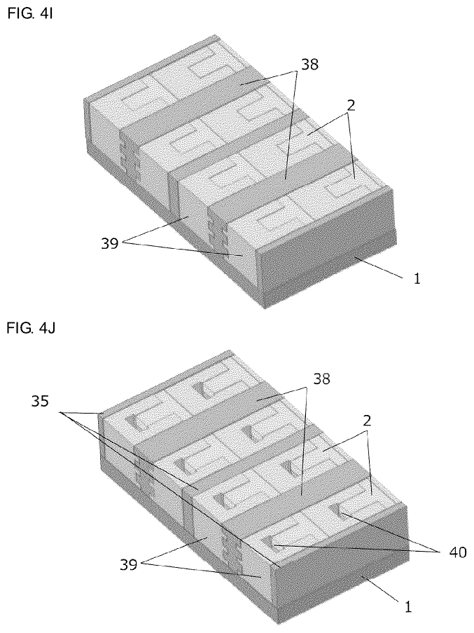

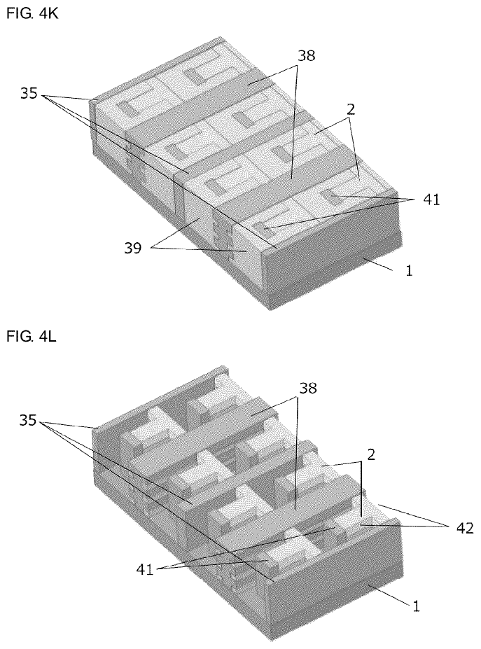

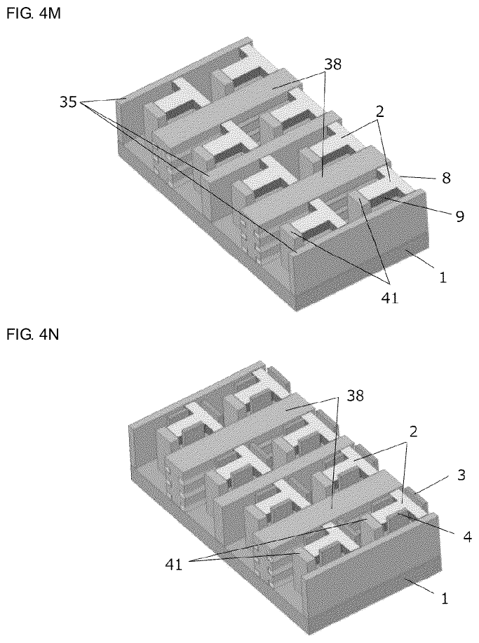

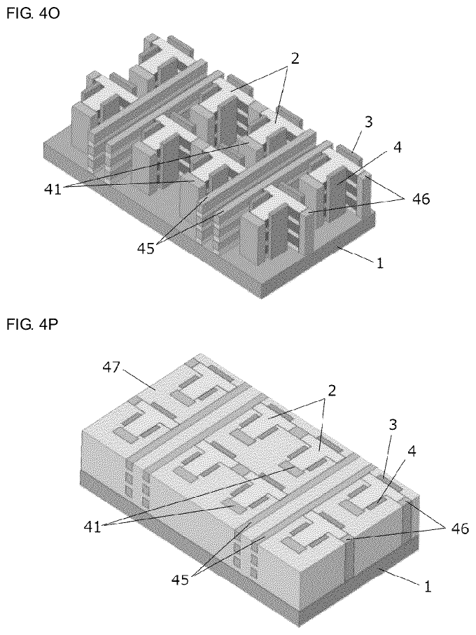

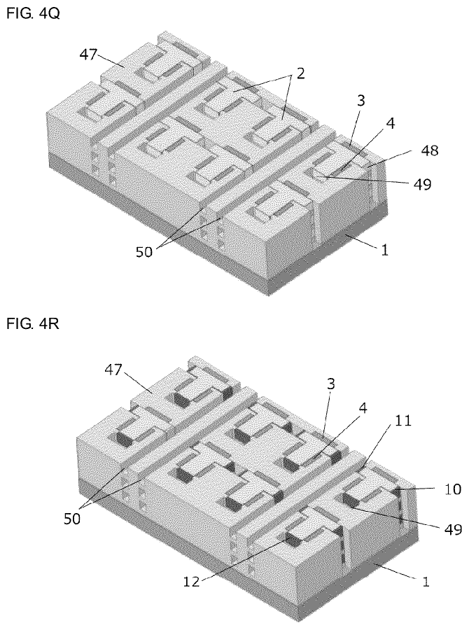

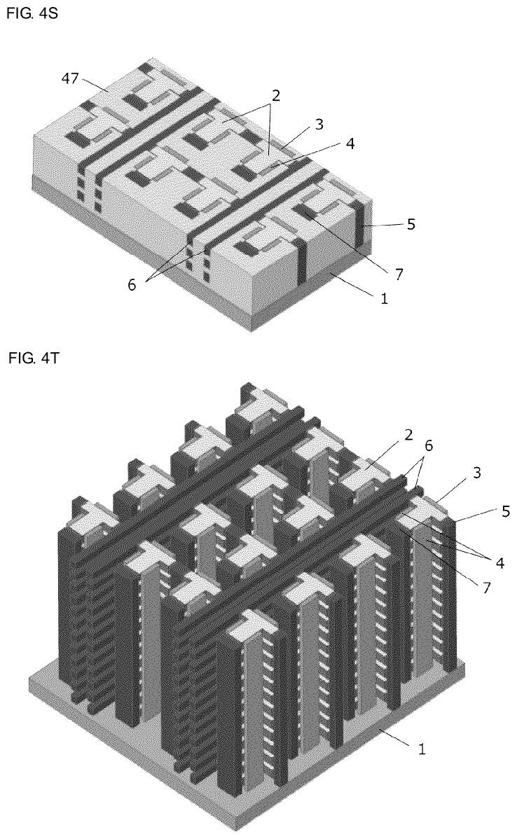

Next, a method of manufacturing the three-dimensional laminated memory cell array according to the first embodiment of the present invention will be described with reference to FIG. 4A to FIG. 4S. FIG. 4A to FIG. 4S are schematic partial bird's eye views illustrating embodiments of steps of a method of forming a three-dimensional laminated memory device.

As illustrated in FIG. 4A, a first semiconductor layer 30 and a second semiconductor layer 31 are alternately epitaxially grown on a monocrystalline semiconductor substrate 1 by using a chemical vapor deposition (CVD) method. At this time, the first semiconductor layer 30 is, for example, a Si layer, and the second semiconductor layer 31 is, for example, a Si(1-x)Gex layer. The first semiconductor layer 30 is a semiconductor layer containing a P-type impurity. The value of x of the second semiconductor layer 31 can be appropriately selected in a range from 0.05 to 0.5, and this value is more preferably in a range from 0.2 to 0.4 in order to reduce a strain between the second semiconductor layer 31 and the first semiconductor layer 30. The thickness of one layer of the second semiconductor layer 31 may be selected as appropriate as long as the thickness is 5 nm or more, and is more preferably in a range from 5 nm to 100 nm. The thickness of one layer of the first semiconductor layer 30 may be selected as appropriate as long as the thickness is 5 nm or more, and is more preferably in a range from 10 nm to 100 nm. The number of layers in a laminated structure 32 in which the first semiconductor layer 30 and the second semiconductor layer 31 are alternately deposited is not limited, and the object of the present embodiment can be attained by deposition of one or more layers of the first semiconductor layer 30 and one or more layers of the second semiconductor layer 31.

Next, as illustrated in FIG. 4B, only the second semiconductor layer 31 is selectively removed by etching while the first semiconductor layer 30 is left, and the space formed thereby is filled with a first dielectric layer 33 by using, for example, a CVD method or an atomic layer deposition (ALD) method. In this case, as a method of selectively etching and removing only the second semiconductor layer 31, one of a dry etching method without using plasma, a reactive ion etching method using plasma, and a wet etching method using a chemical solution, or a combination of a plurality of these methods can be used. The first dielectric layer 33 may use, for example, a silicon oxide (SiO2) film.

Next, as illustrated in FIG. 4C, a desired pattern is formed in a portion of a region for forming a memory cell array by using a photolithography method, and then a laminated film of the first semiconductor layer 30 and the first dielectric layer 33 is vertically etched by using a reactive ion etching method to form a first slit region 34. Next, as illustrated in FIG. 4D, the first slit region 34 is filled with a second dielectric layer 35 of a type different from that of the first dielectric layer 33 by using, for example, a CVD method or an ALD method. The second dielectric layer 35 may use, for example, a silicon nitride (SiN) film.

Next, as illustrated in FIG. 4E, a desired pattern is formed in a portion of the region for forming the memory cell array by using a photolithography method, and then the laminated film of the first semiconductor layer 30 and the first dielectric layer 33 is vertically etched by using a reactive ion etching method to form a second slit region 36, thereby exposing side portions of the first semiconductor layer 30.

Next, as illustrated in FIG. 4F, only a region of the first semiconductor layer 30 that is exposed in the second slit region 36 and is at a desired distance from a side wall is selectively removed by etching while the first dielectric layer 33 is left to form a recessed region 37. As a method of selectively etching and removing only the desired region of the first semiconductor layer 30, one of a dry etching method without using plasma, a reactive ion etching method using plasma, and a wet etching method using a chemical solution, or a combination of a plurality of these methods can be used.

Next, as illustrated in FIG. 4G, the second slit region 36 and the recessed region 37 are filled with a third dielectric layer 38 by using, for example, a CVD method or an ALD method. At this time, the third dielectric layer 38 is a film of a type different from that of the first dielectric layer 33, and can use, for example, a SiN film.

However, the first dielectric layer 33 and the third dielectric layer 38 are not necessarily limited to the above-described types of films, and the object of the present invention can be attained by any one of a dry etching method without using plasma, a reactive ion etching method using plasma, and a wet etching method with a chemical solution, as long as the first dielectric layer 33 and the third dielectric layer 38 have different etching rates and the third dielectric layer 38 filling the recessed region 37 has a higher etching rate than that of the first dielectric layer 33.

Next, as illustrated in FIG. 4H, a desired pattern is formed in a portion of the region for forming the memory cell array by using a photolithography method, and then the laminated structure made of the first semiconductor layer 30 and the first dielectric layer 33 is vertically etched to a desired depth by using an anisotropic reactive ion etching method using plasma, thereby forming a memory cell 2.

Next, as illustrated in FIG. 4I, the space around the memory cell 2 is filled with a fourth dielectric layer 39 by using, for example, a chemical vapor deposition (CVD) method, an atomic layer deposition (ALD) method, or a solution coating method. The fourth dielectric layer 39 is a film of a type different from that of the third dielectric layer 38, and can use, for example, a SiO2 film.

Next, as illustrated in FIG. 4J, a desired pattern is formed by using a photolithography method in a region in contact with a portion of the memory cell 2 in the region constituting the memory cell array, and then the fourth dielectric layer 39 is vertically etched to a desired depth by using an anisotropic reactive ion etching method using plasma, thereby forming a bottom electrode hole 40.

Next, as illustrated in FIG. 4K, the bottom electrode hole 40 is filled with a fifth dielectric layer 41 by using, for example, a CVD method, an ALD method, or a solution coating method. The fifth dielectric layer 41 is preferably, for example, a film of a type equivalent to the type of the third dielectric layer 38, and can use, for example, a SiN film.

Next, as illustrated in FIG. 4L, only the fourth dielectric layer 39 in the region for forming the memory cell array is vertically etched to a desired depth by using an anisotropic reactive ion etching method using plasma to expose side portions 42 of the memory cell 2.

Next, as illustrated in FIG. 4M, a word line gate insulating layer 8 and a plate line gate insulating layer 9 are formed at the memory cell side portions 42. The word line gate insulating layer 8 and the plate line gate insulating layer 9 may be an oxide of the first semiconductor layer 30 constituting the memory cell 2, a transition metal oxide layer, or a laminated film thereof, and can be formed by, for example, a thermal oxidation method, a plasma oxidation method, a deposition method using a CVD method, an ALD method, or the like, or a combination thereof.

Next, for example, a polycrystalline Si layer is deposited as a gate electrode layer on the entire surface by using, for example, a CVD method, and as illustrated in FIG. 4N, only desired regions of the polycrystalline Si layer are left by using a photolithography method and an anisotropic reactive ion etching method using plasma, thereby forming a word line gate electrode 3 and a plate line gate electrode 4. At this time, the word line gate electrode 3 and the plate line gate electrode 4 are electrically insulated between different memory cells 2 adjacent to each other in the same plane, and are electrically connected between different memory cells 2 adjacent to each other in the vertical direction with respect to the substrate and insulated by the first dielectric layer 33.

The material of the word line gate electrode 3 and the plate line gate electrode 4 is not limited to polycrystalline Si, and may be another metal film or a laminated metal film that can be deposited by a CVD method, an ALD method, or the like, such as a laminated film of a TiN film and a W film.

Next, as illustrated in FIG. 4O, only desired regions of the second dielectric layer 35 and the third dielectric layer 38 are left by using a photolithography method and an anisotropic reactive ion etching method using plasma, thereby forming a dummy bit line region 45 and a dummy source line region 46.

Then, as illustrated in FIG. 4P, the space between memory cells 2 is filled with a sixth dielectric layer 47 by using, for example, a CVD method, an ALD method, or a solution coating method. The sixth dielectric layer 47 is preferably, for example, a film of a type equivalent to the type of the first dielectric layer 33, and can use, for example, a SiO2 film. However, this does not imply any limitation, and the object of the present invention can be attained as long as the sixth dielectric layer 47 is constituted of a material having a lower etching rate for an etching chemical solution or an etching gas than those of at least the second dielectric layer 35, the third dielectric layer 38, and the fifth dielectric layer 41.

Next, as illustrated in FIG. 4Q, the second dielectric layer 35 constituting the dummy source line region 46, the third dielectric layer 38 constituting the dummy bit line region 45, and the fifth dielectric layer 41 are selectively removed while the sixth dielectric layer 47 is left by one of a reactive ion etching method using plasma and a wet etching method using a chemical solution, or a combination thereof, thereby forming a dummy source line hole 48, a dummy bottom line hole 49, and a dummy bit line hole 50. At this time, end portions of the first semiconductor layer 30 constituting the memory cell 2 are exposed in the formed dummy source line hole 48, dummy bottom line hole 49, and dummy bit line hole 50.

Next, as illustrated in FIG. 4R, a source impurity region 10, a drain impurity region 11, and a bottom impurity region 12 that are constituted of a semiconductor region containing an impurity having a polarity opposite to that of an impurity contained in the first semiconductor layer 30 are formed on surfaces where the end portions of the first semiconductor layer 30 are exposed in the dummy source line hole 48, the dummy bottom line hole 49, and the dummy bit line hole 50. At this time, the impurity contained in the first semiconductor layer 30 is, for example, boron (B) exhibiting P-type, and the impurity contained in the source impurity region 10, the drain impurity region 11, and the bottom impurity region 12 is, for example, arsenic (As) exhibiting N-type.

The source impurity region 10, the drain impurity region 11, and the bottom impurity region 12 may be formed, for example, by selectively growing a semiconductor layer containing an impurity having a polarity opposite to that of the impurity contained in the first semiconductor layer 30 deposited by using a selective vapor phase epitaxial growth method; by depositing a polycrystalline or amorphous semiconductor film containing an impurity having an opposite polarity, then performing heat treatment to selectively deposit a monocrystalline semiconductor region on the surfaces where the first semiconductor layer 30 is exposed in the dummy source line hole 48, the dummy bottom line hole 49, and the dummy bit line hole 50, and then removing only the deposited polycrystalline or amorphous semiconductor film; by depositing a metal thin film of an impurity having an opposite polarity by using, for example, a CVD method, and then performing heat treatment to disperse the impurity in the surfaces where the first semiconductor layer 30 is exposed; or by performing heat treatment in an atmosphere of a gas containing a metal element of an impurity having an opposite polarity.

Next, as illustrated in FIG. 4S, a source line 5, a bit line 6, and a bottom line 7 are formed by filling the dummy source line hole 48, the dummy bottom line hole 49, and the dummy bit line hole 50 with a metal wiring layer. The metal wiring layer filling the source line 5, the bit line 6, and the bottom line 7 can be formed by using, for example, one of a CVD method, an ALD method, an electrolytic plating method, and an electroless plating method, or a combination of two or more of these methods. The metal layer may be formed of, for example, a laminated film of a titanium nitride (TiN) film and a tungsten (W) film, a laminated film of a titanium nitride (TiN) film and a tungsten silicide (WSix) film, or a laminated film of a tantalum nitride (TaN) film and a copper (Cu) film. However, this does not imply any limitation, and the object of the present invention is attained as long as a material that enables proper electric connection with the source impurity region 10, the drain impurity region 11, and the bottom impurity region 12 is used.

By the processes described above, a cell array of a three-dimensional laminated memory device with a three-dimensional laminate is formed, in which a plurality of memory cells are constituted of memory cells 2, word line gate electrodes 3, plate line gate electrodes 4, source lines 5, bit lines 6, and bottom lines 7, the memory cells arranged perpendicularly to the substrate 1 are electrically connected by the word line gate electrodes 3, the plate line gate electrodes 4, and the source lines 5 formed perpendicularly to the substrate, and the memory cells arranged on the same plane with the bit lines 6 formed in parallel to the substrate 1 are electrically connected by the bit lines 6.

FIG. 4T is a schematic partial perspective view illustrating a cell array of the formed three-dimensional laminated memory device with the three-dimensional laminate in an easily understandable manner, in which the sixth dielectric layer 47 is not illustrated.

Although the SiO2 film is used for the sixth dielectric layer 47 in the above-described embodiment, the SiO2 film may be a low dielectric constant SiO2 (Low-K SiO2) film having a lower dielectric constant than that of normal SiO2.

Moreover, in the above-described embodiment, the source impurity region 10, the drain impurity region 11, and the bottom impurity region 12 containing the impurity having the polarity opposite to that of the impurity contained in the first semiconductor layer 30 are formed after the second dielectric layer 35, the third dielectric layer 38, and the fifth dielectric layer 41 are removed by etching. However, the process position does not imply any limitation, and, for example, the source impurity region 10, the drain impurity region 11, and the bottom impurity region 12 may be formed in each process after the second slit region 36 illustrated in FIG. 4E is formed, after the recessed region 37 illustrated in FIG. 4F is formed, and after the bottom electrode hole 40 illustrated in FIG. 4J is formed, and the object of the present invention can be attained as long as the formation is performed at least before the source line 5, the bottom line 7, and the bit line 6 are formed.

Moreover, in the method of the above-described embodiment, the method of forming the structure in which the source line 5 and the bit line 6 are orthogonal to each other has been described. However, it is needless to say that a structure in which the source line 5 and the bit line 6 are parallel to each other can be formed, for example, as described in the fourth embodiment illustrated in FIG. 2C. In this case, it is not necessary to separately form the dummy source line hole for forming the source line and the dummy bit line hole for forming the bit line, and the source line and the bit line can be formed in the same process. Thus, the cell array of the three-dimensional laminated memory device can be formed in a shorter process.

Moreover, in the above-described embodiment, for example, as illustrated in FIG. 4S, the space between two adjacent bit lines 6 formed in parallel is filled with the sixth dielectric layer 47. However, a structure may be employed in which the space between the two adjacent bit lines is not completely filled with the sixth dielectric layer 47, and an air gap is formed. Moreover, similarly to this, for example, a structure may be employed in which an air gap is formed between the source line 5d illustrated in FIG. 2C, the source line 5e illustrated in FIG. 2D, the source line 5f illustrated in FIG. 2E, and the adjacent source lines formed in parallel to these lines.

Moreover, in the method of the above-described embodiment, as illustrated in FIG. 4A, the first semiconductor layer 30 and the second semiconductor layer 31 are alternately epitaxially grown on the monocrystalline semiconductor substrate 1 by using a chemical vapor deposition (CVD) method, the first semiconductor layer 30 is, for example, the Si layer, the second semiconductor layer 31 is, for example, the Si(1-x)Gex layer, and the first semiconductor layer 30 is the semiconductor layer containing the P-type impurity. However, the manufacturing method of the present invention is not limited thereto. The first semiconductor layer 30 may be a polycrystalline Si(Poly-Si) layer containing a P-type impurity, an insulating layer of, for example, SiO2 may be used instead of the second semiconductor layer 31, the aforementioned polycrystalline Si(Poly-Si) layer containing the P-type impurity may be converted into a monocrystalline Si layer by using a technique called metal induced lateral crystallization (MILC).

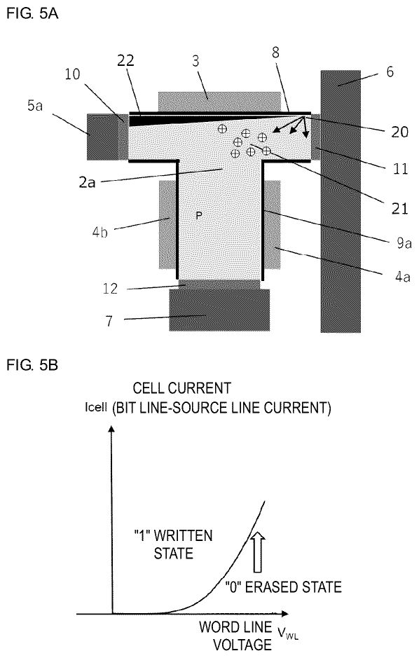

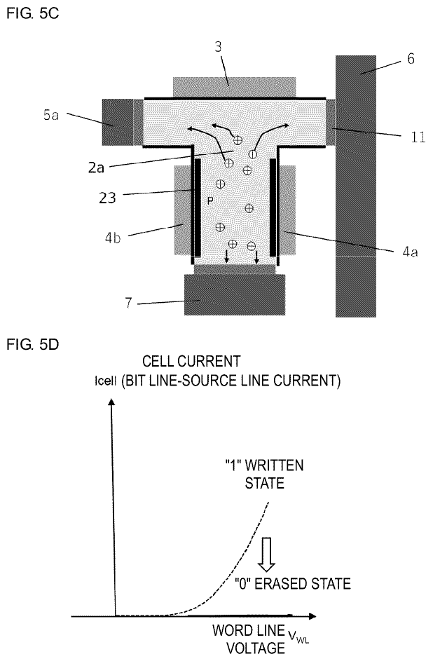

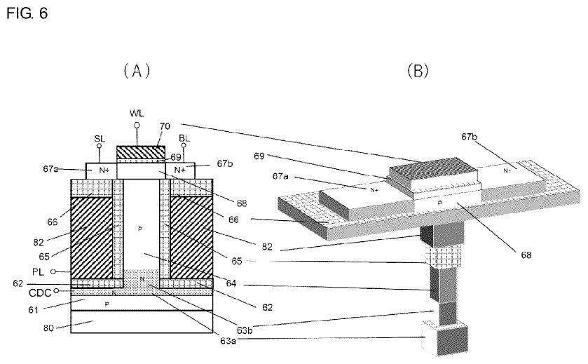

Next, an operation method of a three-dimensional laminated memory cell will be described. FIGS. 5A to 5D of this embodiment are schematic views illustrating an operation method of the three-dimensional laminated memory cell of the first embodiment. In this memory cell, the memory operation is performed by controlling the voltage to be applied to the source line 5, the bit line 6, the plate line gate electrode 4, the word line gate electrode 3, and the bottom line 7 illustrated in FIG. 5A. In the structure of this embodiment, the threshold voltage of the MOSFET formed under the word line gate electrode 3 can be changed by controlling the positive hole concentration in the memory cell 2 constituted of the P-type semiconductor.

For example, 0 V is input to the source line 5a illustrated in FIG. 5A, for example, a positive voltage is input to the bit line 6, and, for example, a negative voltage is applied to the plate line gate electrodes 4a and 4b. Next, when a voltage higher than the threshold voltage before writing of the MOSFET in contact with the word line gate electrode 3 is input to the word line gate electrode 3, a partial inversion layer 22 is formed immediately below the word line gate insulating layer 8 in contact with the word line gate electrode 3, and a pinch-off point 20 is formed. As a result, the electric field becomes maximum between the pinch-off point 20 and the drain impurity region 11 in the MOSFET including the word line gate electrode 3, and an impact ionization phenomenon occurs in this region, thereby generating electron-positive hole pairs. The generated positive holes are diffused toward a region having a lower positive hole concentration due to the concentration gradient. Moreover, part of the generated electrons flows into the word line gate electrode 3; however, most of the generated electrons flow into the drain impurity region 11 connected to the bit line 6. As a result, a positive hole group 21 is accumulated in the memory cell 2a.

As a result, as illustrated in FIG. 5B, the threshold voltage of the MOSFET connected to the word line gate electrode 3 is lowered by a positive substrate bias effect due to the positive holes temporarily accumulated in the memory cell 2a, as compared with that before the writing. This written state is assigned to logical memory data “1”.

Next, as illustrated in FIG. 5C, in an erase operation, the voltage of the source line 5, the bit line 6, the word line gate electrode 3, and the bottom line 7 is set to 0 V. Moreover, the voltage of the plate line gate electrodes 4a and 4b is set to a positive voltage. As a result, an inversion layer 23 of electrons is formed at the interface between the plate line gate insulating layer 9 and the memory cell 2a regardless of the value of the initial potential of the memory cell 2a. Thus, the positive holes accumulated in the memory cell 2a flow from the memory cell 2a to the inversion layer 23 and recombine with electrons. Part of the positive holes also flows into the drain impurity region 11, the source impurity region 10, and the bottom impurity region 12, and also recombine with electrons. As a result, the positive hole concentration of the memory cell 2a decreases with time, and as illustrated in FIG. 5D, the threshold voltage of the MOSFET becomes higher than that when “1” is written, and the memory cell 2a returns to the initial state. The erased state of this memory is logical memory data “0”.

By the above-described operation, the logical memory data “1” or “0” is written in the memory cell 2a, and by applying an appropriate word line voltage and measuring the current flowing in the MOSFET, the written information can be discriminated.

The embodiments have the following features.

### Feature 1

The three-dimensional laminated memory device according to the embodiments of the present invention is constituted of the structure in which the plurality of memory cells arranged in parallel and perpendicularly to the substrate are electrically connected by the word line gate electrode, the plate line gate electrode, and the bottom line formed perpendicularly to the substrate, and the plurality of memory cells arranged on the same plane parallel to the substrate are electrically connected by the bit line formed in parallel to the substrate. Thus, by increasing the number of laminated layers as compared with a dynamic flash memory device of related art in which memory cells are arranged two-dimensionally, an increase in three-dimensional density of the memory cell array can be easily attained, and a significant increase in capacity of the memory device and a significant reduction in bit unit cost can be attained.

### Feature 2

In the three-dimensional laminated memory device according to the embodiments of the present invention, since the volume of the semiconductor region sandwiched by the plate lines for accumulating carriers of the memory cell can be freely adjusted without a change in the thickness in the vertical direction with respect to the substrate, the number of carriers accumulated at the time of writing can be easily increased, and the margin of the memory operation can be widened without a significant change in the manufacturing process.

### Feature 3

In the three-dimensional laminated memory device according to the embodiments of the present invention, a metal layer having a low resistance can be used for the bottom electrode, and hence, as compared with a dynamic flash memory of related art using a semiconductor layer having a high resistance for the bottom electrode, a reduction in power consumption and an increase in the speed of the memory operation can be attained.

The present invention is not limited to the above-described embodiments, and various embodiments and modifications can be made without departing from the broad spirit and scope of the present invention. The above-described embodiments each are intended to describe an embodiment of the present invention, and do not limit the scope of the present invention. It is needless to say that the present invention can be applied to a structure in which the embodiments are combined and a structure in which various modifications are made without departing from the gist of the present invention, and the above-described embodiments and modifications can be desirably combined. Further, even when the constituent requirements of the above-described embodiments are partially removed as necessary, the resultant is within the scope of the technical idea of the present invention.

By using the semiconductor element according to the present invention, a three-dimensional laminated memory device with a higher density and a lower bit cost than those of related art can be provided.

What is claimed is:

1. A three-dimensional laminated memory device comprising:
a plurality of memory cells in which a semiconductor layer and a first insulating layer are alternately laminated on a substrate in a vertical direction with respect to the substrate,
wherein in a first memory cell included in the plurality of memory cells, the semiconductor layer is made of a first semiconductor layer extending in a first direction and a second semiconductor layer connected to one side of the first semiconductor layer and extending in a second direction orthogonal to the first direction in a plan view, and
wherein the first memory cell includes
a first impurity region and a second impurity region in contact with both respective ends of the first semiconductor layer in the first direction in the plan view,
a third impurity region in contact with an end portion of the second semiconductor layer opposite to an end portion thereof in contact with the first semiconductor layer in the plan view,
a first gate insulating layer in contact with a side surface of the first semiconductor layer opposite to a side surface thereof in contact with the second semiconductor layer, and a first gate conductor layer in contact with the first gate insulating layer in the plan view,
a second gate insulating layer and a third gate insulating layer in contact with both side surfaces of the second semiconductor layer in the plan view, and
a second gate conductor layer in contact with the second gate insulating layer, and a third gate conductor layer in contact with the third gate insulating layer.

2. The three-dimensional laminated memory device according to claim 1,
wherein a second memory cell having a same structure as a structure of the first memory cell is laminated in the vertical direction with respect to the substrate,
wherein a gate conductor layer of the second memory cell corresponding to the first gate conductor layer of the first memory cell is connected to the first gate conductor layer in the vertical direction,
wherein a gate conductor layer of the second memory cell corresponding to the second gate conductor layer of the first memory cell is connected to the second gate conductor layer in the vertical direction, and
wherein a gate conductor layer of the second memory cell corresponding to the third gate conductor layer of the first memory cell is connected to the third gate conductor layer in the vertical direction.

3. The three-dimensional laminated memory device according to claim 2,
wherein the first memory cell includes a first wiring conductor layer extending in the second direction in a same plane parallel to the substrate and being in contact with the first impurity region, and
wherein the first wiring conductor layer is in contact with an impurity region of a third memory cell corresponding to the first impurity region, the third memory cell being adjacent to the first memory cell in the second direction in the same plane parallel to the substrate and having a same structure as structures of the first and second memory cells.

4. The three-dimensional laminated memory device according to claim 2,
wherein the first memory cell includes a third wiring conductor layer extending in the vertical direction with respect to the substrate and being in contact with the third impurity region, and
wherein the third wiring conductor layer is in contact with an impurity region of the second memory cell corresponding to the third impurity region.

5. The three-dimensional laminated memory device according to claim 2,
wherein the first memory cell includes a second wiring conductor layer extending in the vertical direction with respect to the substrate and being in contact with the second impurity region, and
wherein the second wiring conductor layer is in contact with an impurity region of the second memory cell corresponding to the second impurity region.

6. The three-dimensional laminated memory device according to claim 5,
wherein a fourth memory cell having a structure mirror-symmetrical to the structure of the first memory cell with respect to a plane being perpendicular to the substrate and extending in the second direction is adjacent to the first memory cell in the first direction in a same plane parallel to the substrate, and
wherein an impurity region of the fourth memory cell corresponding to the second impurity region of the first memory cell is in contact with the second wiring conductor layer in contact with the second impurity region of the first memory cell.

7. The three-dimensional laminated memory device according to claim 4,
wherein a fifth memory cell having a structure mirror-symmetrical to the structure of the first memory cell with respect to a plane being perpendicular to the substrate and extending in the first direction is adjacent to the first memory cell in the second direction in a same plane parallel to the substrate, and
wherein an impurity region of the fifth memory cell corresponding to the third impurity region of the first memory cell is in contact with the third wiring conductor layer in contact with the third impurity region of the first memory cell.

8. The three-dimensional laminated memory device according to claim 1, wherein the second semiconductor layer extending in the second direction of the first memory cell is arranged such that a distance between the second semiconductor layer and the first impurity region is different from a distance between the second semiconductor layer and the second impurity region.

9. The three-dimensional laminated memory device according to claim 8,
wherein a sixth memory cell has a structure in which the first memory cell is rotated by 180 degrees with respect to an axis perpendicular to the substrate in a same plane parallel to the substrate,
wherein the sixth memory cell is adjacent to the first memory cell in the second direction in the same plane parallel to the substrate,
wherein the second gate conductor layer of the first memory cell is adjacent to a position facing a gate conductor layer of the sixth memory cell corresponding to the second gate conductor layer of the first memory cell, and
wherein the first wiring conductor layer in contact with the first impurity region of the first memory cell is in contact with an impurity region of the sixth memory cell corresponding to the second impurity region of the first memory cell.

10. The three-dimensional laminated memory device according to claim 3,
wherein the first memory cell includes a fourth wiring conductor layer extending in the second direction in the same plane parallel to the substrate and being in contact with the second impurity region, and
wherein the fourth wiring conductor layer is in contact with an impurity region of the third memory cell corresponding to the second impurity region of the first memory cell, the third memory cell being adjacent to the first memory cell in the second direction in the same plane parallel to the substrate.

11. The three-dimensional laminated memory device according to claim 7,
wherein the first memory cell includes a fifth wiring conductor layer extending in the second direction in the same plane parallel to the substrate and being in contact with the second impurity region, and
wherein the fifth wiring conductor layer is in contact with an impurity region of a fifth memory cell corresponding to the second impurity region of the first memory cell, the fifth memory cell being adjacent to the first memory cell in the second direction in the same plane parallel to the substrate.

12. The three-dimensional laminated memory device according to claim 9,
wherein the first memory cell includes a sixth wiring conductor layer extending in the second direction in the same plane parallel to the substrate and being in contact with the second impurity region, and
wherein the sixth wiring conductor layer is in contact with an impurity region of the sixth memory cell corresponding to the second impurity region of the first memory cell, the sixth memory cell being adjacent to the first memory cell in the second direction in the same plane parallel to the substrate.
